(19) United States
(12) Patent Application Publication
(10) Pub. No.: US 2008/0045035 A1
(43) Pub. Date: Feb. 21, 2008

(54) Etching solution for etching metal layer, etching method using the etching solution, and method of fabricating semiconductor product using the etching solution

(76) Inventors: Ji-Sung Lee, Seongnam-si (KR); Dong-Min Kang, Uiwang-si (KR); Young Nam Kim, Suwon-si (KR); Young-Sam Lim, Bucheon-si (KR); Yun-Deok Kang, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 11/783,978

(22) Filed: Apr. 13, 2007

(30) Foreign Application Priority Data
Aug. 17, 2006 (KR) 10-2006-0077512

(51) Int. Cl. H01L 21/461; B44C 1/22; C09K 13/06

(52) U.S. Cl. 438/754; 216/41; 252/79.4; 257/E21.002

(57) ABSTRACT

A metal etching solution may include nitric acid, hydrochloric acid, organic acid and water. A semiconductor product fabricating method may include forming a seed layer on a substrate with a metal pad, forming a sacrificial layer that may have an opening exposing the seed layer on the substrate with the seed layer, forming a gold bump that may fill the opening of the sacrificial layer by performing gold electroplating, removing the sacrificial layer, and etching the seed layer exposed by the gold bump, using an etching solution that may include nitric acid, hydrochloric acid, organic acid and water.

### BACKGROUND OF THE INVENTION

1. Field of the Invention

The present invention relates to an etching solution, an etching method using the etching solution, and semiconductor product fabricating methods using the etching solution. More particularly, the present invention relates to a metal etching solution for etching a metal layer, a metal etching method using the metal etching solution, and a semiconductor product fabricating method using the metal etching solution.

2. Description of the Related Art

In the field of semiconductor chip fabrication, miniaturization and high density integration of chips has been progressing. The new generation of semiconductor packages may now include configurations that are light, thin, short and small. In accordance with these recent trends, packaging using flip chip technology has been developed. Specifically, a gold bump process may be used for tape automated bonding (TAB) technology used for drive ICs for LCD devices, CMOS image sensors (CIS), drive ICs for PDPs, etc.

A related art gold bump technology may entail sequentially forming a barrier layer and a current film on a substrate, depositing a photo-resist layer that may include an opening to expose a predetermined region of the current film, filling a gold bump in the opening of the photo-resist layer using a gold electroplating method, and sequentially removing the photo-resist layer and the current film exposed by the gold bump and the barrier layer. The current film may be composed of a gold layer to act as a seed layer for gold electroplating.

The current film, i.e., the seed layer, may be etched using an etching solution containing nitric acid, hydrochloric acid and water. When etching the seed layer, the etching solution may be in a concentration that does not affect the piping of wet-type etching equipment, and the etching speed of the seed layer is slow. In order to improve the etching speed of the seed layer, the nitric acid and hydrochloric acid content of the etching solution may be increased. However, increasing the content of nitric acid and hydrochloric acid may deleteriously affect the piping of the wet-type etching equipment.

### SUMMARY OF THE INVENTION

The present invention is therefore directed to a metal etching solution which substantially overcomes one or more of the problems due to the limitations and disadvantages of the related art.

It is therefore a feature of an embodiment of the present invention to provide a metal etching solution containing an organic acid.

It is therefore a feature of an embodiment to provide a method of fabricating semiconductor products using the metal etching solution.

At least one of the above and other features and advantages of the present invention is to provide a metal etching solution that may include nitric acid, hydrochloric acid, organic acid and water, where a content of the organic acid may be less than a content of the nitric acid.

The hydrochloric acid content may be less than the nitric acid content. The organic acid content may be less than the hydrochloric acid content. The nitric acid content may be about 20 to 40 wt %, the hydrochloric acid content may be about 3 to 18 wt %, and the organic acid content may be about 0.1 to 3 wt %. The organic acid may include ascorbic acid or fatty acid. The fatty acid may include at least one selected from oxalic acid, citric acid, acetylsalicylic acid, acetic acid, propionic acid, butyric acid, glycolic acid, formic acid, lactic acid, malic acid, succinic acid or tartaric acid. The etching solution may etch a metal layer that includes gold. The metal layer may be a gold layer or a gold alloy layer, wherein the gold alloy layer may be Au—Ge layer, Au—Si layer, Au—Be layer, or Au—Zn layer.

At least one of the above and other features and advantages of the present invention is to provide a metal etching method that includes forming a metal layer including gold on a substrate, forming a mask that may partially cover the metal layer, and etching the metal layer exposed by the mask, the metal layer being etched with an etching solution composed of nitric acid, hydrochloric acid, organic acid and water, where a content of the organic acid in the etching solution is less than a nitric acid content.

The hydrochloric acid content may be less than the nitric acid content. The organic acid content may be less than the hydrochloric acid content. The etching solution may contain about 20 to 40 wt % nitric acid, about 3 to 18 wt % hydrochloric acid, and about 0.1 to 3 wt % organic acid. The organic acid may include at least one selected from ascorbic acid or fatty acid, and the fatty acid may include at least one selected from oxalic acid, citric acid, acetylsalicylic acid, acetic acid, propionic acid, butyric acid, glycolic acid, formic acid, lactic acid, malic acid, succinic acid or tartaric acid.

At least one of the above and other features and advantages of the present invention is to provide a method of fabricating a semiconductor product that may include forming a seed layer on a substrate including a metal pad, forming a sacrificial layer that may include an opening for exposing the seed layer on the substrate, forming a gold bump that may fill the opening of the sacrificial layer by gold electroplating, removing the sacrificial layer; and etching the seed layer that may be exposed by the gold bump, with an etching solution that may be composed of nitric acid, hydrochloric acid, organic acid and water.

At least one of the above and other features and advantages of the present invention is to provide a metal etching solution that may be composed of nitric acid, hydrochloric acid, ascorbic acid and water. The composition comprising nitric acid, hydrochloric acid, ascorbic acid and water may be used for etching a metal layer including gold.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIGS. 1 through 5 illustrate stages of a method of fabricating semiconductor products in accordance with an embodiment of the present invention; and

FIG. 6 illustrates a graph of the etching characteristics of a gold (Au) layer, depending on an amount of organic acid added to a metal etching solution containing nitric acid, hydrochloric acid, organic acid and water.

### DETAILED DESCRIPTION OF THE INVENTION

Korean Patent Application No. 10-2006-0077512, filed Aug. 17, 2006, in the Korean Intellectual Property Office, and entitled: “Etching Solution for Etching Metal Layer, Etching Method Using the Etching Solution, and Method of Fabricating Semiconductor Product Using the Etching Solution,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

The present invention may provide an etching solution which improves the etching speed of a metal layer including Au, without increasing the nitric acid content and the hydrochloric acid content. That is, the metal layer including Au may be etched using an etching solution containing nitric acid, hydrochloric acid, organic acid and water. The etching solution of the present invention may etch the metal layer at a desired etching speed without increasing the nitric acid content and the hydrochloric acid content. The content of strong acids such as nitric acid and hydrochloric acid in the etching solution may thus be reduced. This reduction in strong acid content may be advantageous for maintaining and repairing wet-type etching equipment.

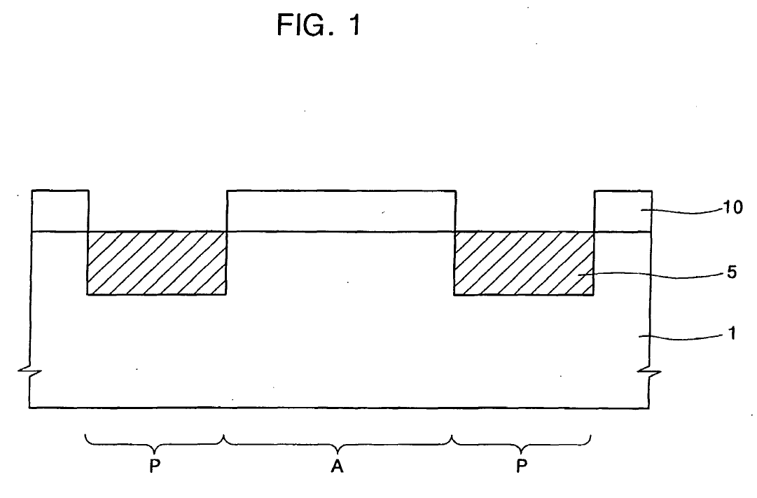

FIGS. 1 through 5 illustrate sectional views of stages of a method of fabricating semiconductor products in accordance with an embodiment of the present invention. In FIGS. 1 through 5, the portion indicated as “P” corresponds to a pad region, and the portion indicated as “A” corresponds to an insulation region.

As illustrated in FIG. 1, a substrate 1 may include the pad region P and the insulation region A. A metal pad 5 may be formed on the substrate 1 at the pad region P. The metal pad 5 may be composed of metal, e.g., aluminum, copper, etc. An insulating layer 10 having an opening for exposing the metal pad 5 may be formed on the substrate 1 including the metal pad 5. The insulating layer 10 may be a passivation layer.

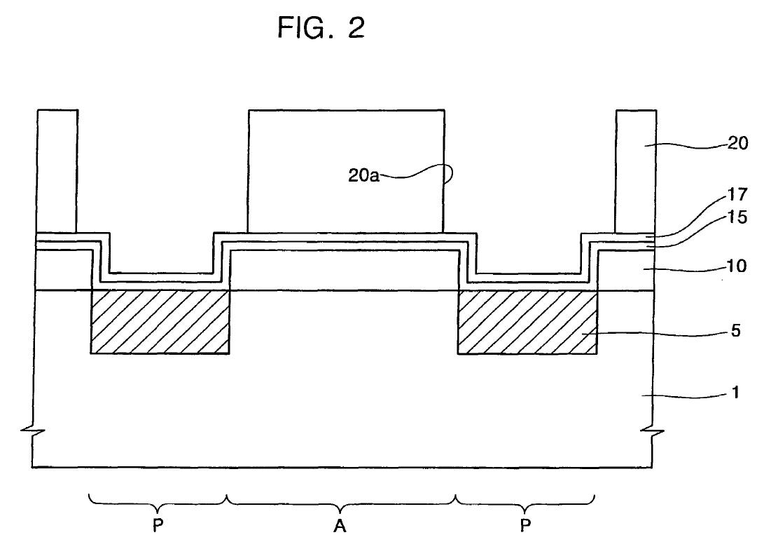

As illustrated in FIG. 2, a barrier layer 15 may be formed on the substrate 1 with the insulating layer 10. The barrier layer 15 may include at least one metal selected from, e.g., titanium (Ti), tungsten (W), tantalum (Ta), etc. The barrier layer 15 may be formed of at least one of, e.g., Ti, W, TiW, Ta, etc.

A seed layer 17 may be used as a seed for gold electroplating. The seed layer 17 may be on the substrate having the barrier layer 15. The seed layer 17 may be composed of a metal layer including, e.g., gold (Au). If the metal layer includes Au, the metal layer may be a Au layer or Au-alloy layer. The Au-alloy layer may be, e.g., a Au—Ge layer, Au—Si layer, Au—Be layer, Au—Zn layer, etc. The seed layer 17 may be deposited by sputtering to increase the adhesiveness with a subsequently formed gold bump. The seed layer 17 may prevent the barrier layer 15 from being oxidized. The seed layer 17 may be formed to a thickness of, e.g., about 100 Å to 5000 Å. The seed layer 17 may also be formed to a thickness of, e.g., about 1000 Å to 3000 Å.

A sacrificial layer 20 having an opening 20a for exposing the seed layer 17 of the pad region P may be formed on the substrate having the seed layer 17. The sacrificial layer 20 may be a positive or negative photoresist layer.

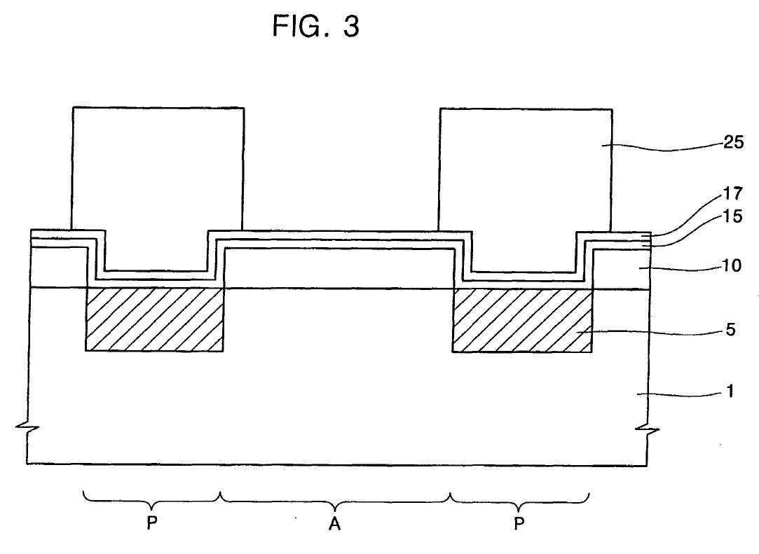

As illustrated in FIG. 3, a gold or gold alloy bump 25 filling the opening 20a of FIG. 2 of the sacrificial layer 20 of FIG. 2 may be deposited by, e.g., a gold electroplating process, in which the seed layer 17 exposed by the opening 20a of FIG. 2 may be used as a seed. The gold bump 25 may be formed to a thickness of about 1 μm to 25 μm, e.g., about 10 μm to 25 μm. Subsequently, the sacrificial layer 20 of FIG. 2 may be selectively removed. The gold bump 25 may partially cover the seed layer 17.

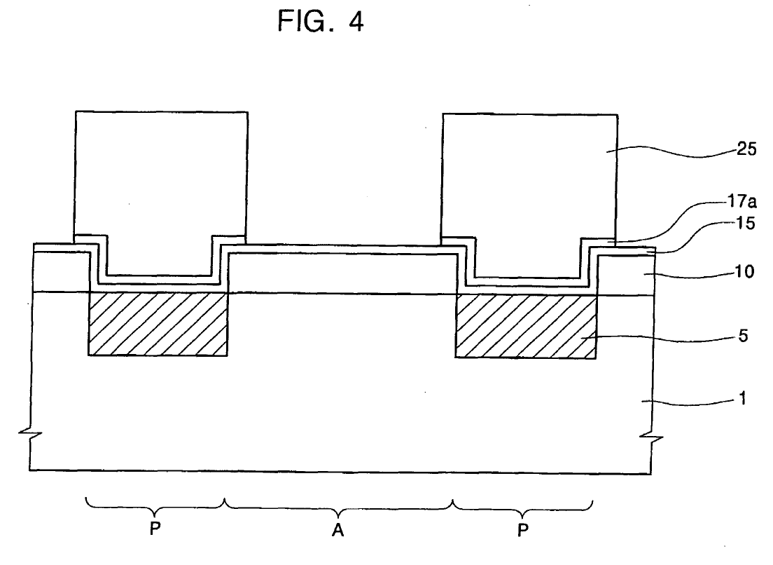

As illustrated in FIG. 4, a seed pattern 17a may be formed by etching the seed layer 17, exposed by the gold bump 25, with a metal etching solution that may contain at least one of nitric acid, hydrochloric acid, organic acid and water. The exposed seed layer 17 may be etched until the barrier layer 15 is exposed. The exposed seed layer 17 may be etched at a temperature of, e.g., about 10° C. to 50° C., and preferably of, e.g., about 20 to 30° C.

In the metal etching solution, the water may be a solvent. The metal etching solution may be formulated by sequentially adding nitric acid, hydrochloric acid and organic acid into the water. The sequence of mixing the water, nitric acid, hydrochloric acid and organic acid may be changed.

In the metal etching solution, the organic acid content may be less than a nitric acid content. That is, in the metal etching solution, the weight ratio (wt %) of organic acid may be less than that of nitric acid. In the metal etching solution, the hydrochloric acid content may be less than the nitric acid content. In the metal etching solution, the organic acid content may be less than the hydrochloric acid content. In the metal etching solution, the weight ratio of each of nitric acid, hydrochloric acid and organic acid may be progressively less in the order of nitric acid, hydrochloric acid and organic acid. That is, in the metal etching solution, the nitric acid content may be greater than the hydrochloric acid content, and the hydrochloric acid content may be greater than the organic acid content.

The metal etching solution may contain, e.g., about 65 wt % or less of nitric acid, about 35 wt % or less of hydrochloric acid, and about 3 wt % or less of organic acid, based on 100 wt % of etching solution, with water making up the balance. Preferably, the metal etching solution may contain, e.g., about 20 to 40 wt % nitric acid, about 3 to 18 wt % hydrochloric acid, about 0.1 to 3 wt % organic acid, with water making up the balance to about 100 wt %. A small amount of surfactant may also be contained in the etching solution. The surfactant may be a cationic, anionic or nonionic surfactant.

The organic acid may include at least one selected from ascorbic acid (C₆H₈O₆) and fatty acids, where the fatty acids may include a carboxyl group (—COOH). The fatty acid may be at least one of oxalic acid (C₂H₂O₄), citric acid (C₆H₈O₇), acetylsalicylic acid (C₉H₈O₄), acetic acid (CH₃COOH), propionic acid (CH₃CH₂COOH), butyric acid (CH₃CH₂CH₂COOH), glycolic acid (HOCH₂COOH), formic acid (HCOOH), lactic acid (CH₃CH(OH)COOH), malic acid (C₄H₆O₅), succinic acid (HOOCCH₂CH₂COOH), and tartaric acid (C₄H₆O₆). Higher chain C₅-C₂₀ fatty acids may also be used.

In the metal etching solution, the nitric acid may act as an oxidizer for oxidizing the seed layer 17, and the hydrochloric acid may remove the oxidized seed layer 17 in a salt form. The organic acid may increase the action of the nitric acid oxidizing the seed layer 17.

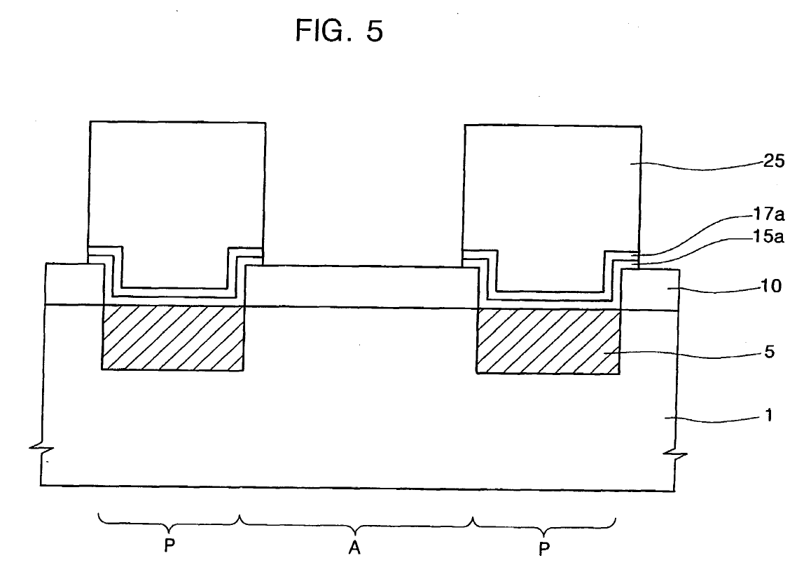

As illustrated in FIG. 5, the exposed barrier layer 15 may be selectively etched. A barrier pattern 15a remaining under the seed pattern 17a may be formed. When the barrier layer 15 is composed of Ti or TiW, the exposed barrier layer 15 may be etched with an etching solution containing hydrogen peroxide (H₂O₂). When the barrier layer 15 is composed of Ta, the exposed barrier layer 15 may be removed using a dilute hydrofluoric acid (HF) solution. The barrier layer 15 may be etched with an etching solution having an etch selectivity with respect to the gold bump 25.

In an embodiment of the invention, the etching solution may be used for a method of fabricating metal interconnections, which may be composed of a gold layer and/or a gold-alloy layer. The method of forming this type of metal interconnection will be described with reference to FIGS. 3 through 5. According to this method, a metal layer (17 of FIG. 3) including Au may be formed on a substrate 1. A mask (25 of FIG. 3) partially covering the metal layer (17 of FIG. 3) may be deposited, and an etching process may be performed using the inventive metal etching solution, so that the metal layer (17 of FIG. 3) exposed by the mask (25 of FIG. 3) may be etched to form a metal interconnection (17a of FIG. 4). The mask (25 of FIG. 5) may removed (not shown).

### EXPERIMENTAL EXAMPLES

The Experimental Examples determine an etching rate, i.e., etching speed, of gold (Au) layers using an etching solution in accordance with embodiments of the present invention compared to general etching solutions of Comparative Examples. Multiple experimental samples are prepared by sputtering Au layers each having a thickness of about 1000 Å on silicon substrates. The removal time using different etching solutions is measured to calculate the etching speed (Å/sec) of the Au layer. Table 1 shows the results of calculating the etching speed (Å/sec) of the Au layer for different etching solutions. Experimental Examples 1 through 5 in Table 1 show the results of etching the Au layer using etching solutions containing organic acids in accordance with the present invention, to demonstrate the improvement in the etching speed of the Au layer without increasing the nitric acid content and the hydrochloric acid content. Comparative Examples 1 through 4 in Table 1 show the etching speed of the Au layer as a function of changes in the nitric acid content and the hydrochloric acid content in etching solutions containing of nitric acid, hydrochloric acid and water.

TABLE 1

| | | nitric | | citric | formic | acetic | ascorbic | etching |
|---|---|---|---|---|---|---|---|---|
| | hydrochloric | acid | water | acid | acid | acid | acid | speed |
| | acid (wt %) | (wt %) | (wt %) | (wt %) | (wt %) | (wt %) | (wt %) | (Å/sec) |
| Comparative | 12 | 10 | 78 | | | | | 8 |
| Example 1 | | | | | | | | |
| Comparative | 18 | 10 | 72 | | | | | 11 |
| Example 2 | | | | | | | | |
| Comparative | 6 | 19 | 75 | | | | | 16 |
| Example 3 | | | | | | | | |
| Comparative | 6 | 29 | 65 | | | | | 53 |
| Example 4 | | | | | | | | |
| Experimental | 6 | 29 | 64.4 | 0.6 | | | | 55 |
| Example 1 | | | | | | | | |
| Experimental | 6 | 29 | 64.4 | | 0.6 | | | 57 |
| Example 2 | | | | | | | | |
| Experimental | 6 | 29 | 64.1 | | 0.6 | 0.3 | | 70 |
| Example 3 | | | | | | | | |
| Experimental | 6 | 29 | 64.7 | | | 0.3 | | 77 |
| Example 4 | | | | | | | | |
| Experimental | 6 | 29 | 63.2 | | | | 1.8 | 135 |
| Example 5 | | | | | | | | |

Comparative Examples 1 and 2 have the same nitric acid content. However, Comparative Example 2 utilizes an etching solution containing relatively high hydrochloric acid content, as compared to Comparative Example 1. The etching speed of the Au layer is observed to be higher in Comparative Example 2. The etching speed thus increases with increasing hydrochloric acid content in the etching solution.

Upon comparing Comparative Examples 2 and 3, the combined content of the hydrochloric acid and nitric acid of the etching solution of Comparative Example 2 is about 28 wt %, and the combined content of the hydrochloric acid and nitric acid of the etching solution of Comparative Example 3 is about 25 wt %. However, the etching speed of Comparative Example 2 may be slower than that of Comparative Example 3, even though Comparative Example 2 has a higher content of hydrochloric acid and nitric acid than that of Comparative Example 3. The etching speed may be observed to increase when hydrochloric acid is mixed with nitric acid at an appropriate ratio. That is, the etching speed of the Au layer may increase by decreasing the hydrochloric acid content and increasing the nitric acid content. The etching speed may increase when the nitric acid content is higher than the hydrochloric acid content.

Comparative Examples 3 and 4 both have the same hydrochloric acid content. However, Comparative Example 4 uses an etching solution with relatively high nitric acid content, as compared to Comparative Example 3. The etching speed of the Au layer is observed to be higher in Comparative Example 4. Accordingly, the etching speed may increase with an increasing weight ratio of nitric acid in the etching solution.

Comparative Examples 1 through 4 indicate that the etching speed of the Au layer increases as the hydrochloric acid content and the nitric acid content in the etching solution increase. However, the increase of the hydrochloric acid content and the nitric acid content may result in not only increasing the etching speed, but also in affecting the piping of wet-type etching equipment. Furthermore, it may be undesirable to increase the use nitric acid and hydrochloric acid in view of environment pollution. Consequently, it may be undesirable to increase the content of nitric acid and hydrochloric acid.

In comparison, the etching speed of the Au layer in Experimental Examples 1 through 5 is observed to be higher than Comparative Example 4 even though the content of hydrochloric acid and nitric acid does not increase. The etching solutions used in Experimental Examples 1 through 5 contain organic acid in addition to hydrochloric acid, nitric acid and water. In the etching solutions containing nitric acid, hydrochloric acid, organic acid and water, Experimental Example 1 contains about 0.6 wt % citric acid, Experimental Example 2 contains about 0.6 wt % formic acid, Experimental Example 3 contains about 0.6 wt % formic acid and about 0.3 wt % acetic acid, Experimental Example 4 contains about 0.3 wt % acetic acid, and Experimental Example 5 contains about 1.8 wt % ascorbic acid.

In Experimental Examples 1 through 5, although the etching speed differs depending on the kind and content of organic acid, the etching speed of the Au layer commonly increases further than is observed in Comparative Example 4. When the etching solution containing hydrochloric acid, nitric acid, organic acid and water is used to etch the Au layer, the etching speed of the Au layer is observed to improve without increasing the content of hydrochloric acid and nitric acid in the etching solution. This means that productivity may be improved, and this improvement may be accompanied by a reduction of the amount of hydrochloric acid and nitric acid utilized in a wet-type etching process. In other words, as the amount of hydrochloric acid and nitric acid is reduced, the time and cost required for maintaining and repairing the piping of the wet-type etching equipment may be reduced. Even if the same amount of hydrochloric acid and nitric acid as that of a general etching solution is used, the etching speed of the Au layer in the wet-type etching process is improved, thereby reducing the process time.

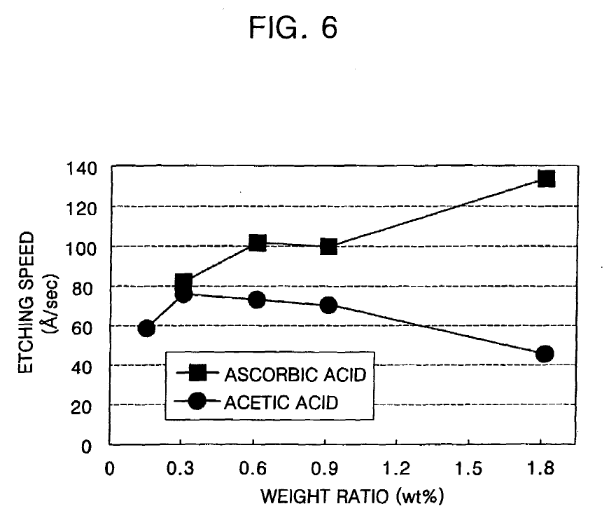

FIG. 6 illustrates a graph of the etching characteristics of the Au layer, depending on an amount of organic acid to be added in a metal etching solution composed of nitric acid, hydrochloric acid, organic acid and water. In FIG. 6, the x-axis denotes the weight ratio of organic acid, e.g., ascorbic acid and acetic acid, in the etching solution, and the y-axis denotes the etching speed (Å/sec) of a Au layer.

Similar to the experimental results in Table 1, the results of FIG. 6 are obtained by preparing experimental samples in which the Au layer with a thickness of about 1000 Å is sputtered on a silicon substrate. The measuring time for removing the Au layer is measured using etching solutions containing hydrochloric acid, nitric acid, organic acid and water. The etching solutions include consistent hydrochloric acid and nitric acid contents but different organic acid content. The etching solutions used in the experimental samples commonly include about 6 wt % hydrochloric acid and about 29 wt % nitric acid of. Ascorbic acid and acetic acid are used as the different organic acids contained in the etching solutions.

In FIG. 6, the data indicated by “-▪-” denotes the etching speed of the Au layer as a function of the change of the ascorbic acid content in the etching solutions. The data indicated by “--” denotes the etching speed of the Au layer as a function of the change of the acetic acid content in the etching solutions.

As illustrated in FIG. 6, the etching speed of the Au layer may increase as the ascorbic acid content increases. That is, when the ascorbic acid in the etching solution is about 0.3 wt %, the etching speed of the Au layer is about 82 Å/sec, and when ascorbic acid is about 1.8 wt %, the etching speed of the Au layer is about 135 Å/sec. In Comparative Example 4 of Table 1, when the Au layer is etched using an etching solution containing about 6 wt % hydrochloric acid and about 29 wt % nitric acid (with water making up the balance), the etching speed is about 53 Å/sec. However, when the Au layer is etched using an etching solution containing about 6 wt % hydrochloric acid and about 29 wt % nitric acid, ascorbic acid being less than the amount of hydrochloric acid, and water making up the balance, the etching speed may be higher than observed in Comparative Example 4. This result indicates that adding ascorbic acid into the etching solution may increase the etching speed of the Au layer without increasing the nitric acid and hydrochloric acid content in the etching solution.

The graph in FIG. 6 shows that the etching speed of the Au layer may change as the acetic acid content increases in the etching solution. Specifically, the nitric acid content and the hydrochloric acid content in the etching solution are about 29 wt % and about 6 wt %, respectively. As the acetic acid content increases in the etching solution at this weight ratio of nitric acid and hydrochloric acid, the etching speed of the Au layer initially increases and thereafter decreases. That is, in the etching solution containing about 29 wt % nitric acid and about 6 wt % hydrochloric acid, when the acetic acid content is about 0.15 wt %, the etching speed of the Au layer increases to about 58 Å/sec. When the acetic acid content is about 0.3 wt %, the etching speed of the Au layer increases to about 77 Å/sec, and when the acetic acid content is about 0.6 wt %, the etching speed decreases to about 75 Å/sec. Further, when the acetic acid content in the etching solution is about 1.8 wt %, the etching speed is about 46 Å/sec, which is lower than the etching speed when the etching solution of Comparative Example 4 is used. This result infers that the etching speed of the Au layer does not continuously increase as the acetic acid content increases, even though the content of organic acid such as acetic acid may increases. Accordingly, results may be optimized when an organic acid such as acetic acid in the etching solution is less than the nitric acid content. Further, excellent results may be obtained when organic acid such as acetic acid in the etching solution is less than the hydrochloric acid content.

From the experimental results, it is observed that the etching speed of etching the Au layer using the organic acid-containing etching solution in accordance with the present invention may be higher than that using the general etching solution containing nitric acid, hydrochloric acid and water. That is, the general etching solutions of the Comparative examples contain no organic acid. These results mean that the hydrochloric acid content and the nitric acid content may be reduced in the etching solution of the present invention, and the same or better results than those of the general etching solution may be obtained. Furthermore, the etching solution in accordance with the present invention increases the etching speed of the gold-containing metal layer using the same weight ratios of nitric acid and hydrochloric acid as the general etching solution.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A metal etching solution, comprising:
nitric acid, hydrochloric acid, organic acid and water, wherein an amount of the organic acid is less than an amount of the nitric acid.

2. The metal etching solution as claimed in claim 1, wherein an amount of the hydrochloric acid is less than the amount of nitric acid.

3. The metal etching solution as claimed in claim 1, wherein an amount of the organic acid is less than an amount of the hydrochloric acid.

4. The metal etching solution as claimed in claim 1, wherein a content of the nitric acid is about 20 to 40 wt %, a content of the hydrochloric acid is about 3 to 18 wt %, and a content of the organic acid is about 0.1 to 3 wt %.

5. The metal etching solution as claimed in claim 1, wherein the organic acid is at least one selected from ascorbic acid or fatty acid.

6. The metal etching solution as claimed in claim 5, wherein the fatty acid is at least one selected from oxalic acid, citric acid, acetylsalicylic acid, acetic acid, propionic acid, butyric acid, glycolic acid, formic acid, lactic acid, malic acid, succinic acid, or tartaric acid.

7. The metal etching solution as claimed in claim 1, wherein the metal etching solution etches a metal layer including gold.

8. The metal etching solution as claimed in claim 7, wherein the metal layer is a gold layer or a gold-alloy layer, the gold-alloy layer being an Au—Ge layer, Au—Si layer, Au—Be layer or Au—Zn layer.

9. A metal etching method, comprising:
forming a metal layer including gold on a substrate;
forming a mask partially covering the metal layer; and
etching the metal layer exposed by the mask, the metal layer being etched with an etching solution composed of nitric acid, hydrochloric acid, organic acid and water, wherein a content of the organic acid in the etching solution is less than a content of the nitric acid.

10. The metal etching method as claimed in claim 9, wherein the metal layer comprises a gold layer or a gold-alloy layer, the gold-alloy layer being an Au—Ge layer, Au—Si layer, Au—Be layer, or Au—Zn layer.

11. The metal etching method as claimed in claim 9, wherein the etching solution contains less of the hydrochloric acid than the nitric acid.

12. The metal etching method as claimed in claim 9, wherein the etching solution contains less of the organic acid than the hydrochloric acid.

13. The method etching method as claimed in claim 9, wherein the etching solution contains about 20 to 40 wt % of the nitric acid, about 3 to 18 wt % of the hydrochloric acid, and about 0.1 to 3 wt % of the organic acid.

14. The metal etching method as claimed in claim 9, wherein the organic acid is at least one selected from ascorbic acid or fatty acid.

15. The metal etching method as claimed in claim 14, wherein the fatty acid is at least one selected from oxalic acid, citric acid, acetylsalicylic acid, acetic acid, propionic acid, butyric acid, glycolic acid, formic acid, lactic acid, malic acid, succinic acid, or tartaric acid.

16. A method of fabricating a semiconductor, comprising:
forming a seed layer on a substrate having a metal pad;
forming a sacrificial layer having an opening exposing the seed layer on the substrate having the seed layer;
forming a gold bump filling the opening of the sacrificial layer by gold electroplating;
removing the sacrificial layer; and
etching the seed layer exposed by the gold bump, with an etching solution of nitric acid, hydrochloric acid, organic acid and water.

17. The method as claimed in claim 16, wherein the seed layer is a metal layer having gold, the metal layer being a gold layer or a gold alloy layer, the gold alloy layer being an Au—Ge layer, Au—Si layer, Au—Be layer, or Au—Zn layer.

18. The method as claimed in claim 16, wherein the etching solution contains less of the organic acid than the nitric acid.

19. The method as claimed in claim 16, wherein the etching solution contains less of the hydrochloric acid than the nitric acid.

20. The method as claimed in claim 16, wherein the etching solution contains less of the organic acid than the hydrochloric acid.

21. The method as claimed in claim 16, wherein the etching solution contains about 20 to 40 wt % of the nitric acid, about 3 to 18 wt % of the hydrochloric acid, and about 0.1 to 3 wt % of the organic acid.

22. The method as claimed in claim 16, wherein the organic acid is at least one of ascorbic acid or fatty acid.

23. The method as claimed in claim 22, wherein the fatty acid is at least one selected from oxalic acid, citric acid, acetylsalicylic acid, acetic acid, propionic acid, butyric acid, glycolic acid, formic acid, lactic acid, malic acid, succinic acid, or tartaric acid.

24. A metal etching solution, comprising:
nitric acid, hydrochloric acid, ascorbic acid and water.

25. The metal etching solution as claimed in claim 24, wherein the etching solution etches gold.
